(19) United States
(12) Patent Application Publication
(10) Pub. No.: US 2010/0279438 A1
(43) Pub. Date: Nov. 4, 2010

(54) APPARATUS AND METHOD OF IN-SITU IDENTIFICATION FOR CONTAMINATION CONTROL IN SEMICONDUCTOR FABRICATION

(75) Inventors: Su Chao An, Tainan County (TW); Chih-Ming Wan, Tainan County (TW); Bing-Chen Lin, Tainan County (TW); Yang Kai Fan, Tainan County (TW)

Correspondence Address: HAYNES AND BOONE, LLP;IP Section, 2323 Victory Avenue, Suite 700, Dallas, TX, 75219, US

(73) Assignee: TAIWAN SEMICONDUCTOR MANUFACTURING COMPANY, LTD., Hsin-Chu (TW)

(21) Appl. No.: 12/434,014

(22) Filed: May 1, 2009

(51) Int. Cl. H01L 21/66; H01L 21/673

(52) U.S. Cl. 438/14; 414/222.01; 257/E21.529

(57) ABSTRACT

An apparatus is provided that includes a load port for receiving a container that houses a wafer and a detector disposed proximate the load port such that the detector detects a metal characteristic of the wafer. The detected metal characteristic indicates whether the wafer is at a proper location. Also, provided is a method for use in semiconductor manufacture that includes providing a container that houses a wafer, receiving the container in a load port, detecting a metal characteristic of the wafer, and determining whether the wafer is at a proper location based on the detected metal characteristic of the wafer.

### BACKGROUND

The mass production of semiconductor devices utilizes different equipment for different processes. To accomplish this, a single wafer or a lot/batch of wafers may be automatically transported to and from various locations to perform the different processes that are required. Typically, the single wafer or the lot/batch of wafers may be housed in a closed container such as a front opening unified pod (FOUP) and transported by an overhead transport service. At one such location, the FOUP may be placed in a load port that interfaces with a processing tool. However, there may be situations where a wafer intended for another processing tool is misplaced in the FOUP. This can result in cross-contamination and in some situations cause a safety hazard.

### SUMMARY

One of the broader forms of an embodiment of the present invention involves an apparatus. The apparatus includes a load port for receiving a container that houses a wafer and a detector disposed proximate the load port such that the detector detects a metal characteristic of the wafer. The detected metal characteristic indicates whether the wafer is at a proper location.

Another one of the broader forms of an embodiment of the present invention involves a method for use in semiconductor manufacture. The method includes providing a container that houses a wafer, receiving the container in a load port, detecting a metal characteristic of the wafer, and determining whether the wafer is at a proper location based on the detected metal characteristic of the wafer.

Yet another one of the broader forms of an embodiment of the present invention involves a system. The system includes a load port for receiving a container housing a plurality of wafers, a semiconductor processing tool for processing the wafers, a robot for transporting the wafers between the load port and the semiconductor processing tool, and a detector for detecting a magnetic characteristic of at least one of the wafers as the wafers are being transported. The detected magnetic characteristic indicates whether the at least one of the wafers is at a proper location.

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion.

FIG. 1 is a diagrammatic view of a process flow for providing wafers to and from a semiconductor processing tool according to an embodiment of the present disclosure;

FIG. 2 is a flowchart of a method for controlling contamination that can be implemented in the process flow of FIG. 1 according to an embodiment of the present disclosure;

FIG. 3 is a diagrammatic view of an in-situ identification system that can be implemented to perform the method of FIG. 2 according to an embodiment of the present disclosure;

FIG. 4 is a diagrammatic view of a detector that can be implemented in the in-situ identification system of FIG. 3 according to an embodiment of the present disclosure;

FIG. 5 is a flowchart of another method for controlling contamination that can be implemented in the process flow of FIG. 1 according to an embodiment of the present disclosure;

FIG. 6 is a diagrammatic view of another in-situ identification system that can be implemented to perform the method of FIG. 5 according to an embodiment of the present disclosure; and

FIG. 7 is a diagrammatic view of another detector that can be implemented in the in-situ identification system of FIG. 6 according to an embodiment of the present disclosure.

### DETAILED DESCRIPTION

It is to be understood that the following disclosure provides many different embodiments, or examples, for implementing different features of various embodiments. Specific examples of components and arrangements are described below to simplify the present disclosure. These are, of course, merely examples and are not intended to be limiting. In addition, the present disclosure may repeat reference numerals and/or letters in the various examples. This repetition is for the purpose of simplicity and clarity and does not in itself dictate a relationship between the various embodiments and/or configurations discussed. Moreover, the formation of a first feature over or on a second feature in the description that follows may include embodiments in which the first and second features are formed in direct contact, and may also include embodiments in which additional features may be formed interposing the first and second features, such that the first and second features may not be in direct contact.

In semiconductor manufacturing, integrated circuit devices are produced by a plurality of processes in a wafer fabrication facility (referred to as a fab). The integrated circuit devices are typically fabricated by processing one or more wafers as a “lot” (also referred to as a batch) with a series of processing tools at various stations. The lot of wafers may be housed in a container and transported to the various stations by an automated handling system which includes an overhead transport (OHT) service. The lot of wafers includes an identification number (ID) that is used for tracking and recording the lot as it travels throughout the fab. Additionally, the lot ID may provide information regarding what processes and/or recipes may be performed when the lot arrives at the various stations for processing.

In a 300 mm (12 inch) wafer fab, a lot of wafers may be transported in a closed container such as a Front Opening Unified Pod (FOUP) to the various stations where the processing tools are located. At a particular station, the FOUP may be placed in a load port that interfaces with the processing tool. The load port is configured to open and close a lid of the FOUP so that the lot of wafers may be transferred to and from the processing tool via a robot and track module. After processing the lot of wafers, the FOUP may be transported by the OHT service to a next station for further processing. The FOUP and load port may be configured in accordance with standards by SEMI (Semiconductor Equipment and Materials International).

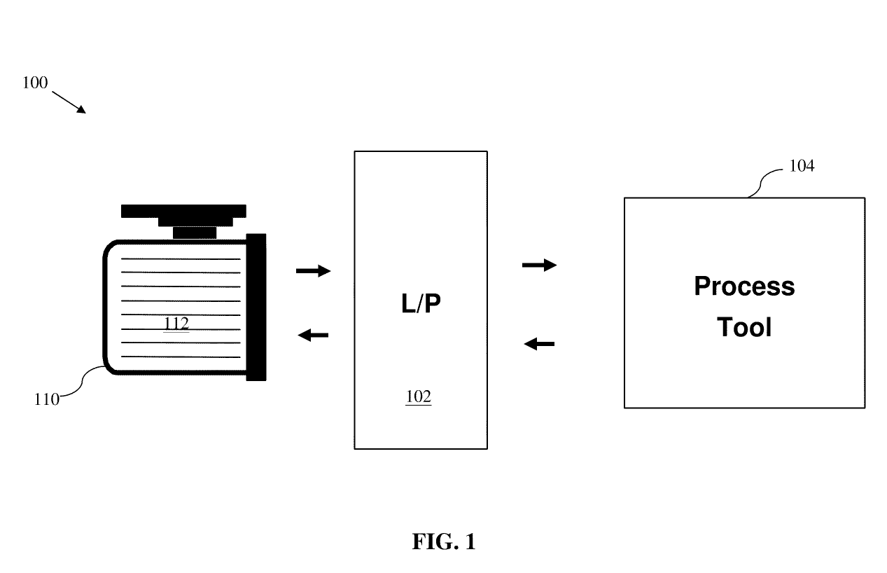

Referring to FIG. 1, illustrated is a diagrammatic view of a process flow 100 for providing wafers to and from a semiconductor processing tool according to one embodiment of the present disclosure. The process flow 100 includes a load port 102 (L/P) configured to load wafers to and from a process tool 104. In an embodiment, the load port 102 may include an input L/P for loading wafers to be processed by the process tool 104 and an output LP for loading wafers that have been processed by the process tool 104. The load port 102 is configured to receive containers such as a FOUP 110 that houses one or more wafers 112. The number of wafers 112 in a lot may vary depending on whether the wafers are for mass production, or for test runs by research/development (R/D), or for a combination thereof. Generally, the FOUP 110 may house a maximum of twenty-five (25) wafers. The FOUP 110 may be transported and placed in the load port 102 by an overhead transport (OHT) service running throughout the fab.

The process tool 104 is operable to perform a process, such as, thermal oxidation, fusion, ion implantation, rapid thermal processing (RTP), chemical vapor deposition (CVD), physical vapor deposition (PVD), epitaxy, etching, cleaning, chemical mechanical polishing (CMP), lithography, or other suitable semiconductor process. The process flow 100 further includes a track-in module configured to transfer wafers 112 between the process tool 104 and the load port 102. The track-in module may include a robot or other suitable device to carry out the transfer.

In wafer fabrication, FOUPs may be identified by groups that are based on stages in the fabrication process to ensure that the FOUPs are being received at the proper stations via the load ports. The groups include a front-end-of-line (FEOL) group, back-end-of-line (BEOL) group, and copper (Cu) group. It is understood that FEOL processing includes processes performed on a wafer up to a first metallization process, and BEOL processing includes processes performed on a wafer from the first metallization process to ship-out. The grouping is implemented due to the concern of cross-contamination between the different stages of wafer fabrication. For example, a FOUP that is supposed to be in the Cu group or the BEOL group can contaminate stations that perform FEOL processing. Accordingly, the load ports include hardware such as pins that are configured to interlock with a particular FOUP. Thus, a FOUP that does not have the proper interlocking mechanism (e.g., pin holes) cannot be received by the load port. However, there may be situations where a wafer is misplaced in an incorrect FOUP group. For example, a wafer having copper layers formed thereon (Cu wafer) may be placed in a FEOL FOUP. In this situation, the mistake is not detected since the FEOL FOUP will be properly received by a load port associated a station that performs FEOL processing. Further, it has been observed that the risk of cross-contamination increases in wafer recycling since transporting the wafer is sometimes performed manually without automated gating.

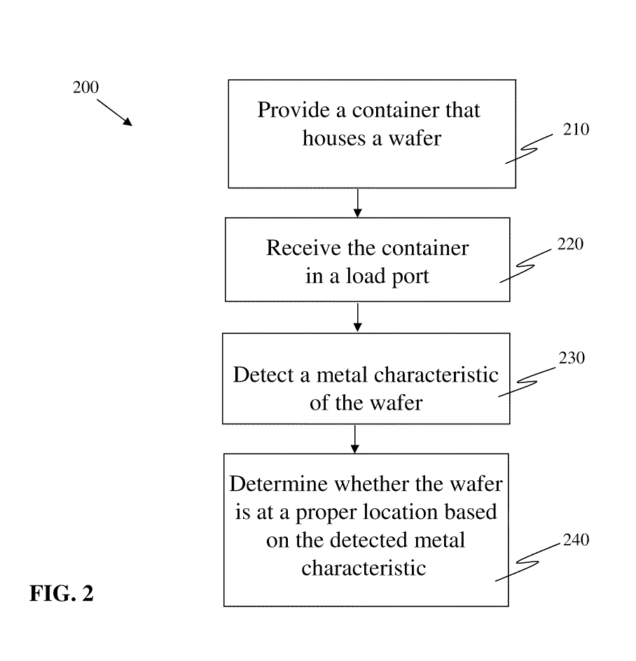

Referring now to FIG. 2, illustrated is a flowchart of a method 200 for controlling contamination in semiconductor fabrication according various aspects of the present disclosure. The method 200 begins with block 210 in which a container that houses a wafer is provided. The container may include a (FOUP). The FOUP may house a single wafer or a lot of wafers for processing in accordance with a recipe. The method 200 continues with block 220 in which the container is received in a load port. The FOUP may be transported by an overhead transport (OHT) service to the load port. The FOUP is received in the load port if the FOUP includes a mechanism that properly interlocks with pins of the load port. For example, the FOUP has to have pin holes that match the pins of the load port in order to be received by the load port.

The method 200 continues with block 230 in which a metal characteristic of the wafer is detected. The lid of the FOUP is opened and a robot is operable to transfer the wafer from the load port to a semiconductor process tool. A detector is disposed proximate the load port and is operable to detect a metal characteristic of the wafer as it is being transported. The metal characteristic includes a magnetic/non-magnetic characteristic of a metal layer formed on the wafer. The method 200 continues with block 240 in which it is determined whether the wafer is at a proper location based on the detected metal characteristic. In an embodiment, if the wafer is detected as having a non-magnetic metal layer, such as Cu, Ta, Al, and W, and the load port is associated with a station that performs FEOL processing, it is determined that the wafer is not at a proper location. These non-magnetic metal layers are typically present in BEOL processing. For example, the load port may be associated with a cleaning process that utilizes an ammonium peroxide mixture (APM). It has been observed that Cu reacts violently with APM which may cause a safety hazard. In another example, the FEOL processing may include a process for forming high-k dielectric films which can be contaminated by wafers having BEOL metal layers. Accordingly, an alarm may be activated to notify an engineer or other suitable operator, and the transfer of the wafer is immediately stopped. In this way, the engineer can verify whether the wafer is at the proper station and can take appropriate action if necessary. In another embodiment, if the wafer is detected as having a non-magnetic metal layer and the load port is associated with a station that performs BEOL processing or Cu processing, it is determined that the wafer is at a proper location, and processing may proceed as intended.

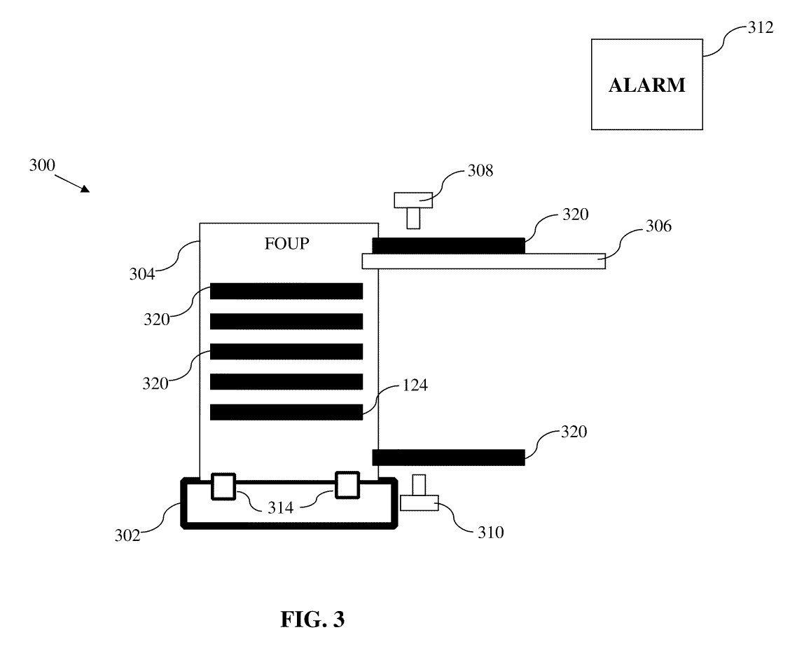

Referring to FIG. 3, illustrated is a diagrammatic view of an in-situ identification system 300 that can be implemented to perform the method 200 of FIG. 2. The in-situ identification system 300 includes a load port 302, a FOUP 304, a robot 306, detectors 308, 310, and an alarm 312. The load port 302 includes pins 314 that are configured to properly interlock with a particular group of the FOUPs, such as FOUP 304. Once the FOUP 304 is properly received in the load port 302, the lid of the FOUP 304 is opened and the robot 306 is operable to transfer wafers 320 to a semiconductor process tool. One detector 308 is positioned proximate the load port 302 such that wafers 320 disposed in an upper portion of the FOUP 304 will pass by the detector 308 when being transported by the robot 306. The other detector 310 is positioned proximate the load port 302 such that wafers 320 disposed in a lower portion of the FOUP 304 will pass by the detector 308 when being transported by the robot 306. The detectors 308, 310 are positioned so that the wafers 320 pass by a sufficient distance from the detectors as will be explained below. It should be noted that the detectors 308, 310 or additional detectors may be positioned at other positions of the in-track module on which the robot travels so that the wafer passes by the detectors before they reach the semiconductor processing tool. Accordingly, a non-magnetic metal characteristic of the wafer can be detected in-situ (within the station), and thus the detectors 308, 310 can function as an additional defense (along with the interlocking pins 314 of the load port 302) for controlling contamination in semiconductor fabrication. The alarm 312 will be activated in situations where the wafer is determined to be at a wrong location.

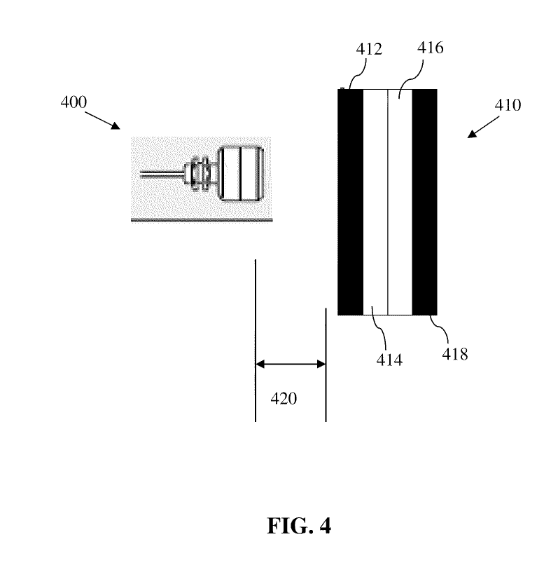

Referring to FIG. 4, illustrated is a diagrammatic view of a detector 400 that can be implemented in the in-situ identification system 300 of FIG. 3. The detector 400 includes various commercially available sensors that are operable to detect a magnetic/non-magnetic characteristic of a metal layer. The detector 400 is operable to detected changes in a magnetic field caused by various metal layers. For example, the detector 400 includes a magnet component and a sensor component. The magnet component generates a magnetic field which changes when the detector 400 is positioned a sufficient distance (or proximity) to a metal layer. The change in the magnetic field is processed, and it can be determined whether the detected metal layer is a non-magnetic metal layer or a magnetic metal layer. In the present example, a wafer 410 has been processed and includes various material layers formed thereon. The wafer 410 comprises a silicon wafer 412, a gate dielectric layer 414, a gate electrode layer 416, and a Cu layer 418. The Cu layer 418 may be part of an interconnect structure formed during metallization in BEOL processing. It is understood that the wafer 410 may comprise other layers but is simplified for the sake of the present discussion. It has been observed that a baseline range for detecting a non-magnetic metal layer, such as Cu, Ta, Al, and W, of a single wafer is not greater than 10 cm. That is, the detector 400 is spaced a distance 420 that is 10 cm or closer in order to detect a non-magnetic metal layer such as the Cu layer 416. Accordingly, at one point in time during the transfer of the wafer 410, the wafer 410 passes by the detector 400 at a distance 420 not greater than 10 cm. Additionally, the specified distance 420 was determined with non-magnetic metal layers having a thickness ranging from 500 angstrom to about 7000 angstrom. For magnetic metal layers, the detector 400 can detect these metal layers at a greater distance than 10 cm.

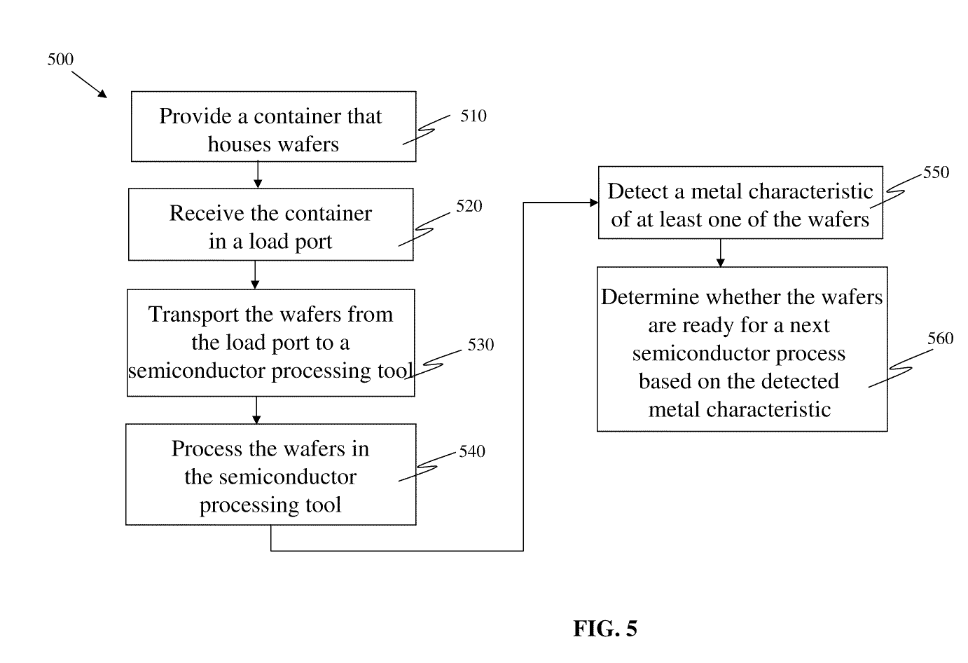

Referring to FIG. 5, illustrated is a flowchart of another method 500 for controlling contamination according to various aspects of the present disclosure. The method 500 begins with block 510 in which a container that houses a plurality of wafers is provided. The container may include a (FOUP). The FOUP may house a lot or batch of wafers for processing in accordance with a recipe. The method 500 continues with block 520 in which the container is received in a load port. The FOUP may be transported by an overhead transport (OHT) service to the load port. The FOUP is received in the load port if the FOUP includes hardware that properly interlocks with pins of the load port.

The method 500 continues with block 530 in which in which the wafers are transported from the load port to a semiconductor processing tool. In the present example, the batch of wafers are transported, via a robot, from the load port to a wet semiconductor process tool such as a dip tank. The dip tank may be associated with BEOL processing. The method 500 continues with block 540 in which the wafers are processed in the semiconductor processing tool. In the present example, a Cu layer has been formed on each of the wafers in the batch, and the batch of wafers are dipped in the tank for a wet etching process. The wet etching process is performed for a duration that is specified by the recipe setting. The wet etching process performed to strip the Cu layer. In some situations, the recipe setting may be incorrect for the particular batch of wafers. Accordingly, the wet etching may not be fully completed to strip the Cu layer, and thus metal residues may remain of the wafers.

The method 500 continues with block 550 in which a metal characteristic of at least on one of the wafers is detected. A detector is disposed proximate the tank and is operable to detect a metal characteristic of the wafers as they are being transported via the robot. The method 500 continues with block 560 in which it is determined whether the wafers are ready for a next semiconductor process based on the detected metal characteristic. In the present example, if any one the wafers in the batch is detected as having a remaining residues of a non-magnetic metal layer, such as Cu, it is determined that the wet etching process has not been fully completed, and thus the wafers is not ready for a next semiconductor process. As previously noted, a possible reason is that an incorrect recipe setting has been applied to the batch of wafers and the Cu layer has not been completely stripped. Accordingly, an alarm may be activated to notify an engineer or other suitable operator, and the transfer of the wafers is stopped immediately. If the wafers are detected as having no metal residues, it is determined that the wafers are ready for the next semiconductor process, and processing may proceed as intended.

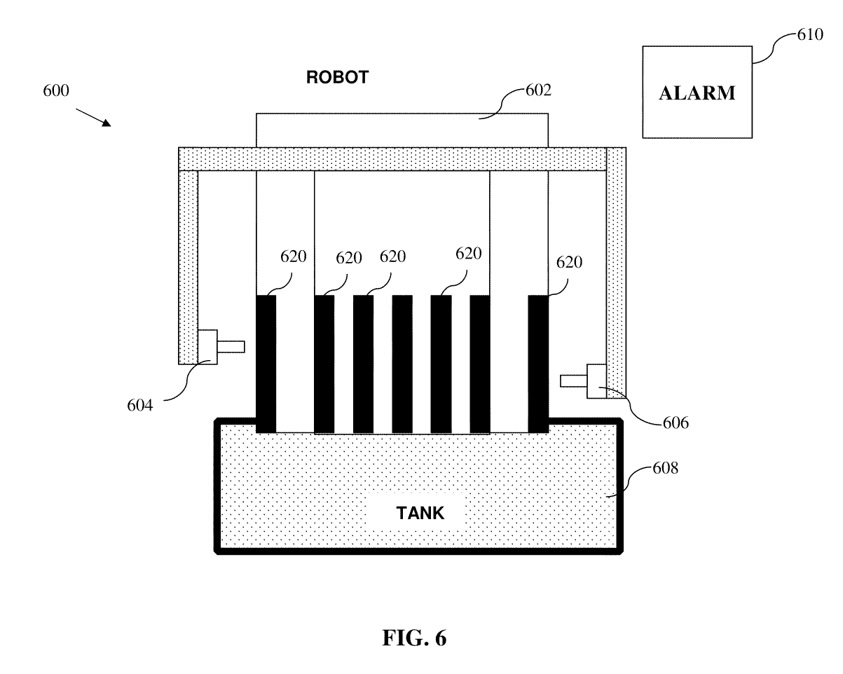

Referring to FIG. 6, illustrated is a diagrammatic view of another in-situ identification system 600 that may be implemented to perform the method 500 of FIG. 5. The in-situ identification system 600 includes a load port (not shown), a FOUP (not shown), a robot 602, detectors 604, 606, a process tank 608, and an alarm 610. As previously noted, once the FOUP is properly received in the load port, the robot 602 is operable to transfer wafers 620 to a semiconductor process tool. In the present embodiment, the robot 602 includes arms that are configured to transfer a batch of wafers 620 to the process tank 608 for a wet etching process. The process tank 608 may be filled with a suitable chemical or etchant. One detector 604 is positioned proximate the tank 608 such that some wafers 620 located at one side of the robot 602 will pass by the detector 604 when being transported by the robot. The other detector 606 is positioned proximate the tank 608 such that some wafers 620 located at the other side of the robot 602 will pass by the detector 606 when being transported by the robot. The detectors 604, 606 are stationary relative to the moving robot 602. The detectors 604, 606 are positioned so that the wafers 620 pass by a sufficient distance from the detectors as will be explained below. It should be noted that the detectors 604, 606 or additional detectors may be positioned at other positions of the in-track module on which the robot travels. Accordingly, a non-magnetic metal characteristic of the wafers can be detected in-situ, and thus the detectors 604, 606 can function as monitor to ensure that the wet etching process is completed before the wafers 620 are transported to the next processing station. The alarm 610 will be activated in situations where one or more of the wafers still have some metal residues following the etching process.

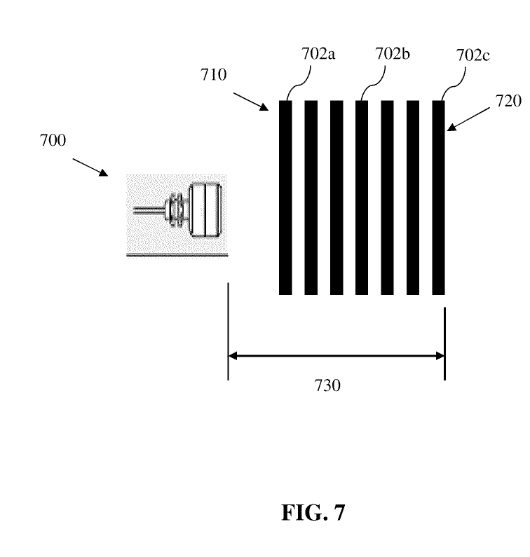

Referring to FIG. 7, illustrated is a diagrammatic view of another detector 700 that can be implemented in the in-situ identification system 600 of FIG. 6. The detector 700 includes various commercially available sensors that are operable to detect a magnetic/non-magnetic characteristic of a metal layer. The detector 700 is operable to detected changes in a magnetic field caused by various metal layers. For example, the detector 700 includes a magnet component and a sensor component. The magnet component generates a magnetic field which changes when the detector 700 is positioned a sufficient distance (or proximity) to a metal layer. The change in the magnetic field is processed, and it can be determined whether the detected metal layer is a non-magnetic metal layer or a magnetic metal layer. In the present example, a batch of wafers 702a-c has been processed. The batch of wafers 702a-c may be positioned with the back surface 710 of the wafer 702 facing the detector 700. In other embodiments, the front surface 720 of the wafer may be facing the detector 700. The wafers 702a-c may or may not have metal residues remaining on the surface. It has been observed that a baseline range for detecting a non-magnetic metal residue, such as Cu, Ta, Al, and W, of a multiple wafers in a batch is not greater than 8 cm. That is, the detector 700 is spaced a distance 730 that is 8 cm or closer from the farthest wafer 702c in order to detect a non-magnetic metal residue on the batch of the wafers 702a-c. Accordingly, at one point in time during the transfer of the wafers 702a-c, the farthest wafer 702c passes by the detector 700 at a distance 730 not greater than 8 cm. Additionally, the specified distance 730 was determined with non-magnetic metal residues having a thickness ranging from 500 angstrom to about 7000 angstrom. For magnetic metal residues, the detector 400 can detect these metal residues at a greater distance than 8 cm.

The foregoing has outlined features of several embodiments so that those skilled in the art may better understand the detailed description that follows. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions and alterations herein without departing from the spirit and scope of the present disclosure. For example, the embodiments disclosed herein are applicable with all fab stations including single wafer type, batch wafer type, wet tools, dry tools, and other proper semiconductor tools and processes. Also, the number of detectors and the location of the detectors may vary depending on the footprint of the process station and/or wafer fab. Further, the in-situ identification system 300 of FIG. 3 can be combined with the in-situ identification system 600 of FIG. 6, and the method 200 of FIG. 2 can be combined with the method 500 of FIG. 5.

What is claimed is:

1. An apparatus, comprising:
a load port for receiving a container that houses a wafer, the load port being associated with a semiconductor processing tool; and
a detector disposed proximate the load port and external to the semiconductor processing tool, the detector being operable to detect a metal characteristic of the wafer, wherein the detected metal characteristic indicates whether the wafer is at a proper location.

2. The apparatus of claim 1, wherein the detector is operable to detect a non-magnetic metal layer disposed on the wafer.

3. The apparatus of claim 2, wherein the non-magnetic metal layer includes one of copper, aluminum, tungsten, tantalum, and titanium.

4. The apparatus of claim 3, wherein the non-magnetic metal layer includes a thickness ranging from about 500 angstrom to about 7000 angstrom.

5. The apparatus of claim 1, wherein the detector is disposed in such a manner that at one point in time the wafer is spaced a distance not greater than 10 cm from the detector when the wafer is being transported from the load port to the semiconductor processing tool.

6. The apparatus of claim 1, wherein the container includes a front opening unified pod (FOUP); and
wherein the detector is disposed proximate a top portion of the FOUP when the FOUP is received by the load port.

7. The apparatus of claim 6, further comprising another detector operable to detect a metal characteristic of another wafer that is housed in the FOUP, the another detector being disposed proximate a bottom portion of the FOUP when the FOUP is received by the load port.

8. The apparatus of claim 1, wherein the detector is operable to detect a magnetic metal layer disposed on the wafer.

9. A method for use in semiconductor manufacture, comprising:
providing a container that houses a wafer;
receiving the container in a load port;
detecting a metal characteristic of the wafer; and
determining whether the wafer is at a proper location based on the detected metal characteristic of the wafer.

10. The method of claim 9, wherein detecting the metal characteristic includes:
disposing a detector proximate the load port; and
moving the wafer in such a manner that at one point in time the wafer is spaced a distance not greater than 10 cm from the detector.

11. The method of claim 9, wherein detecting the metal characteristic includes detecting a magnetic characteristic of a metal layer disposed on the wafer, the magnetic characteristic indicating whether the metal layer is magnetic or non-magnetic.

12. The method of claim 10, further comprising activating an alarm to indicate that the wafer is not at the proper location if the metal layer is non-magnetic and the load port is operatively coupled to a semiconductor processing tool that is operable to perform a front-end-of-line (FEOL) process.

13. The method of claim 9, further comprising:
moving the wafer from the load port to a semiconductor processing tool; and
processing the wafer in the semiconductor processing tool;
wherein detecting the metal characteristic of the wafer is performed after processing the wafer;
wherein determining whether the wafer is at the proper location includes determining whether the processed wafer is ready for a next semiconductor process.

14. The method of claim 13, wherein detecting the metal characteristic includes:
disposing a detector proximate the semiconductor processing tool; and
moving the processed wafer in such a manner that at one point in time the processed wafer is spaced a distance not greater than 8 cm from the detector.

15. A system, comprising
a load port for receiving a container housing a plurality of wafers;
a semiconductor processing tool for processing the wafers;
a robot for transporting the wafers between the load port and the semiconductor processing tool; and
a detector for detecting a magnetic characteristic of at least one of the wafers as the wafers are being transported, wherein the detected magnetic characteristic indicates whether the at least one of the wafers is at a proper location.

16. The system of claim 15, wherein the detector is disposed proximate the load port in such a manner that at one point in time one of the wafers is spaced a distance not greater than 10 cm from the detector when the one of the wafers is being transported.

17. The system of claim 15, wherein the detector is disposed proximate the semiconductor processing tool in such a manner that at one point in time one of the wafers is spaced a distance not greater than 8 cm from the detector when the wafers are being transported.

18. The system of claim 15, wherein the detected magnetic characteristic includes a non-magnetic characteristic of a metal layer disposed on the at least one of the wafers.

19. The system of claim 18, wherein the non-magnetic metal layer includes a thickness ranging from about 500 angstrom to about 7000 angstrom.

20. The system of claim 18, further comprising an alarm that is activated to indicate that the at least one of the wafers is not at the proper location if the semiconductor processing tool is operable to perform a front-end-of-line (FEOL) process.
